(19) United States
(12) Patent Application Publication
(10) Pub. No.: US 2026/0182093 A1
(43) Pub. Date: Jun. 25, 2026

(54) FLIP CHIP LIGHT EMITTING DIODE AND MANUFACTURING METHOD THEREOF

(71) Applicant: Taiwan-Asia Semiconductor Corporation, Hsinchu City (TW)

(72) Inventors: Yu-Tong Hsiao, Hsinchu City (TW); Kun-Li Lin, Hsinchu City (TW); Ching-Yuan Tsai, Hsinchu City (TW); Hong-Ta Cheng, Hsinchu City (TW)

(21) Appl. No.: 19/306,745

(22) Filed: Aug. 21, 2025

(30) Foreign Application Priority Data
Dec. 19, 2024 (TW) 113149743

(51) Int. Cl. H10H 20/831; H10H 20/01; H10H 20/824; H10H 20/833

(52) U.S. Cl. CPC H10H 20/831; H10H 20/0133; H10H 20/032; H10H 20/824; H10H 20/833

(57) ABSTRACT

A flip-chip light-emitting diode and a manufacturing method thereof are provided. The flip-chip light-emitting diode includes a transparent substrate, an epitaxial composite layer, a first conductive type electrode pad, a second conductive type electrode pad, and a wafer bonding composite layer. The epitaxial composite layer is disposed on the transparent substrate, and the first conductive type electrode pad is disposed on the transparent substrate and electrically connected to the epitaxial composite layer. The second conductive type electrode pad is disposed on the epitaxial composite layer, electrically connected to the epitaxial composite layer, and configured on the same level as the first conductive type electrode pad on the same side of the transparent substrate. The wafer bonding composite layer comprises at least one titanium dioxide (TiO₂) layer and at least one silicon dioxide (SiO₂) layer, sandwiched between the epitaxial composite layer and the transparent substrate.

### CROSS-REFERENCES TO RELATED APPLICATIONS

This application claims the benefit of priority to Taiwanese Patent Application No. 113149743 filed on Dec. 19, 2024, which is hereby incorporated by reference in its entirety.

### BACKGROUND OF THE INVENTION

### Field of the Invention

This invention relates to a flip-chip light-emitting diode and a manufacturing method thereof, and in particular to a flip-chip light-emitting diode capable of improving light extraction efficiency and a manufacturing method thereof.

### Descriptions of the Related Art

A Light-Emitting Diode (LED) has advantages such as high brightness, small size, low power consumption, and long lifespan, and is widely applied in lighting or display products. A flip-chip light-emitting diode is one kind of LEDs which adopts an inverted chip design for allowing a large amount of heat generated during the light emission process of the light-emitting layer to be rapidly dissipated through metal electrodes via a substrate or a heat dissipation layer, effectively shortening the heat conduction path, improving heat dissipation efficiency, and reducing light emission decay and performance degradation due to waste heat accumulation. On the other hand, since flip-chip light-emitting diodes do not use metal wires, they will not block the light, thereby improving light extraction efficiency.

However, compared to traditional light-emitting diodes, the manufacturing process and equipment costs of flip-chip light-emitting diodes are relatively high, which is not cost-effective for the development of subsequent application modules or products. Therefore, there is an urgent need in the industry for an innovative flip-chip light-emitting diode structure and manufacturing method to balance the requirements of improving product brightness and maintaining low development costs.

### SUMMARY OF THE INVENTION

The main objective of this invention is to provide a flip-chip light-emitting diode and a manufacturing method thereof. The disclosed light-emitting diode structure can improve light extraction efficiency and reduce complex manufacturing processes, balancing the requirements of enhancing light-emitting diode brightness and maintaining low development costs, thereby increasing the market competitiveness of downstream application products.

To achieve the above objective, this invention provides a flip-chip light-emitting diode comprising a transparent substrate, an epitaxial composite layer, a first conductive type electrode pad, a second conductive type electrode pad, and a wafer bonding composite layer. The epitaxial composite layer is disposed on the transparent substrate, and the first conductive type electrode pad is disposed on the transparent substrate and electrically connected to the epitaxial composite layer. The second conductive type electrode pad is disposed on the epitaxial composite layer, electrically connected to the epitaxial composite layer, and configured on the same level as the first conductive type electrode pad on the same side of the transparent substrate. The wafer bonding composite layer comprises at least one titanium dioxide (TiO₂) layer and at least one silicon dioxide (SiO₂) layer, sandwiched between the epitaxial composite layer and the transparent substrate.

In one embodiment of the flip-chip light-emitting diode of this invention, the thickness of the at least one titanium dioxide layer is 200 to 300 angstroms (Å).

In one embodiment of the flip-chip light-emitting diode of this invention, the wafer bonding composite layer comprises a plurality of titanium dioxide layers and a plurality of silicon dioxide layers, with each titanium dioxide layer and each silicon dioxide layer being alternately stacked.

In one embodiment of the flip-chip light-emitting diode of this invention, the epitaxial composite layer comprises a first compound semiconductor layer, a light-emitting layer, and a second compound semiconductor layer, wherein the first compound semiconductor layer and the second compound semiconductor layer sandwich the light-emitting layer, and the first compound semiconductor layer is disposed between the light-emitting layer and the transparent substrate.

In one embodiment of the flip-chip light-emitting diode of this invention, the first compound semiconductor layer is a first conductive type aluminum gallium arsenide (AlGaAs) layer, and the second compound semiconductor layer is a second conductive type aluminum gallium arsenide layer.

In one embodiment of the flip-chip light-emitting diode of this invention, the flip-chip light-emitting diode further comprises an ohmic contact layer sandwiched between the first conductive type aluminum gallium arsenide layer and the at least one titanium dioxide layer.

In one embodiment of the flip-chip light-emitting diode of this invention, the ohmic contact layer is a gallium phosphide (GaP) layer.

In one embodiment of the flip-chip light-emitting diode of this invention, the interface between the ohmic contact layer and the at least one titanium dioxide layer is a roughened surface.

In one embodiment of the flip-chip light-emitting diode of this invention, the interface between the ohmic contact layer and the at least one titanium dioxide layer is a flat surface.

In one embodiment of the flip-chip light-emitting diode of this invention, the transparent substrate is one of a sapphire (Al₂O₃) substrate, a gallium nitride (GaN) substrate, a zinc oxide (ZnO) substrate, a gallium arsenide (GaAs) substrate, and an indium phosphide (InP) substrate.

To achieve the above objective, this invention provides a manufacturing method of a flip-chip light-emitting diode, comprising the following steps. First, provide an epitaxial composite layer disposed on an epitaxial growth substrate. Provide a wafer bonding composite layer disposed on the epitaxial composite layer, wherein the wafer bonding composite layer comprises at least one titanium dioxide (TiO₂) layer and at least one silicon dioxide (SiO₂) layer. Next, provide a transparent substrate to be wafer-bonded to the wafer bonding composite layer. Subsequently, remove the epitaxial growth substrate; then, provide a first conductive type electrode pad disposed on the transparent substrate and electrically connect to the epitaxial composite layer. Finally, provide a second conductive type electrode pad disposed on the epitaxial composite layer, electrically connect to the epitaxial composite layer, and be configured on the same level as the first conductive type electrode pad on the same side of the transparent substrate.

In one embodiment of the manufacturing method of the flip-chip light-emitting diode of this invention, the thickness of the at least one titanium dioxide layer is 200 to 300 angstroms (Å).

In one embodiment of the manufacturing method of the flip-chip light-emitting diode of this invention, the step of providing a wafer bonding composite layer is to alternately form a plurality of titanium dioxide layers and a plurality of silicon dioxide layers on the epitaxial composite layer, such that each titanium dioxide layer and each silicon dioxide layer are alternately stacked.

In one embodiment of the manufacturing method of the flip-chip light-emitting diode of this invention, the step of providing an epitaxial composite layer is to form a first compound semiconductor layer, a light-emitting layer, and a second compound semiconductor layer, wherein the first compound semiconductor layer and the second compound semiconductor layer sandwich the light-emitting layer, and the second compound semiconductor layer is disposed between the light-emitting layer and the epitaxial growth substrate.

In one embodiment of the manufacturing method of the flip-chip light-emitting diode of this invention, the first compound semiconductor layer is a first conductive type aluminum gallium arsenide (AlGaAs) layer, and the second compound semiconductor layer is a second conductive type aluminum gallium arsenide layer.

In one embodiment of the manufacturing method of the flip-chip light-emitting diode of this invention, further comprising providing an ohmic contact layer sandwiched between the first conductive type aluminum gallium arsenide layer and the at least one titanium dioxide layer.

In one embodiment of the manufacturing method of the flip-chip light-emitting diode of this invention, the ohmic contact layer is a gallium phosphide (GaP) layer.

In one embodiment of the manufacturing method of the flip-chip light-emitting diode of this invention, the step of providing a wafer bonding composite layer is to form the at least one titanium dioxide layer to cover a roughened surface after forming the roughened surface on the ohmic contact layer.

In one embodiment of the manufacturing method of the flip-chip light-emitting diode of this invention, the step of providing a wafer bonding composite layer is to form the at least one titanium dioxide layer on a flat surface of the ohmic contact layer.

In one embodiment of the manufacturing method of the flip-chip light-emitting diode of this invention, the step of providing a transparent substrate is to provide one of a sapphire (Al₂O₃) substrate, a gallium nitride (GaN) substrate, a zinc oxide (ZnO) substrate, a gallium arsenide (GaAs) substrate, and an indium phosphide (InP) substrate.

After referring to the drawings and the embodiments as described in the following, those the ordinary skilled in this art can understand other objectives of the present invention, as well as the technical means and embodiments of the present invention.

### BRIEF DESCRIPTION OF THE DRAWINGS

FIG. 1A to FIG. 1I are schematic diagrams illustrating the manufacturing of a flip-chip light-emitting diode in one embodiment of this invention;

FIG. 2A to FIG. 2F are schematic diagrams illustrating the manufacturing of a flip-chip light-emitting diode in another embodiment of this invention; and

FIG. 3 is a flowchart schematic of the manufacturing process of a flip-chip light-emitting diode in one embodiment of this invention.

### DETAILED DESCRIPTION OF THE PREFERRED EMBODIMENT

In the following description, the present invention will be explained with reference to various embodiments thereof. These embodiments of the present invention are not intended to limit the present invention to any specific environment, application or particular method for implementations described in these embodiments. Therefore, the description of these embodiments is for illustrative purposes only and is not intended to limit the present invention. It shall be appreciated that, in the following embodiments and the attached drawings, a part of elements not directly related to the present invention may be omitted from the illustration, and dimensional proportions among individual elements and the numbers of each element in the accompanying drawings are provided only for ease of understanding but not to limit the present invention.

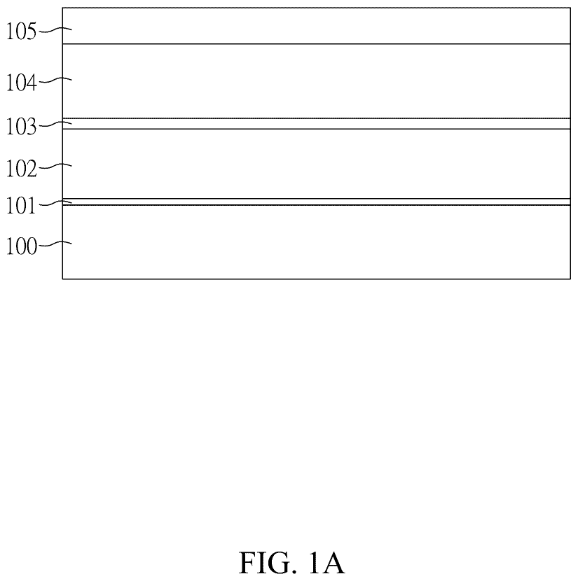

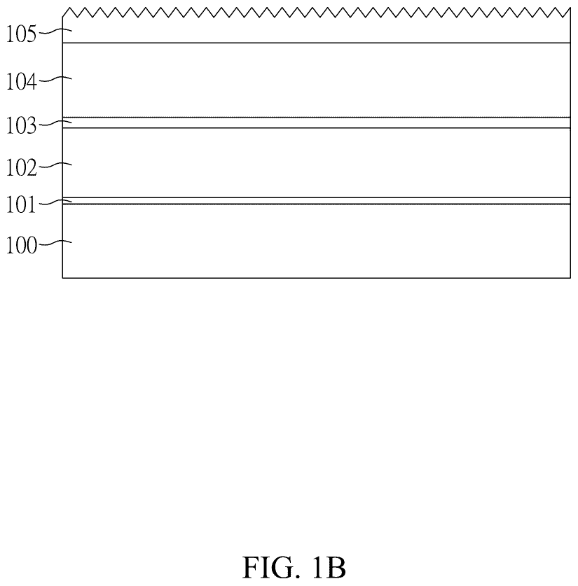

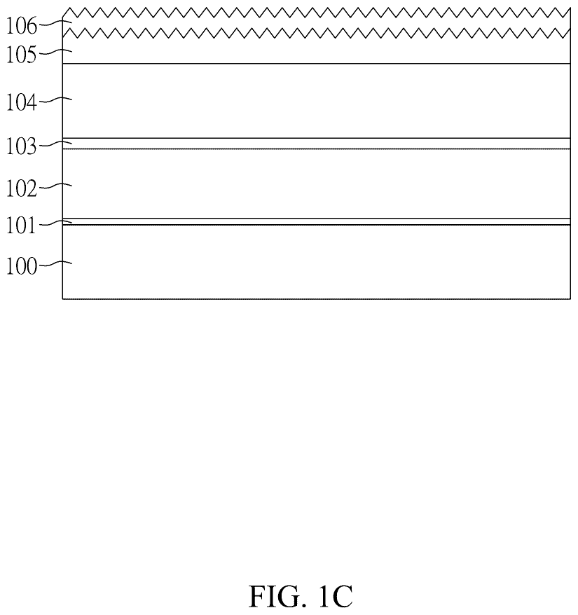

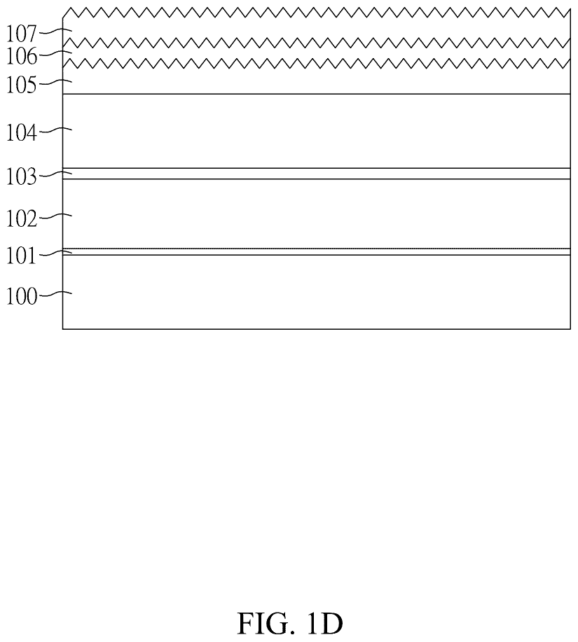

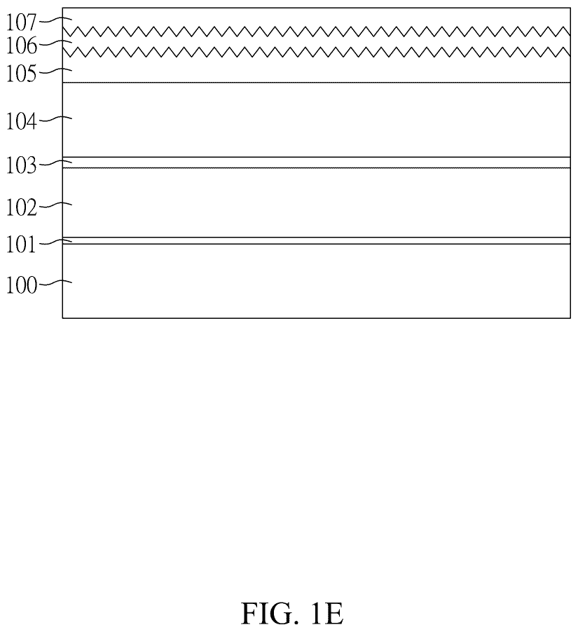

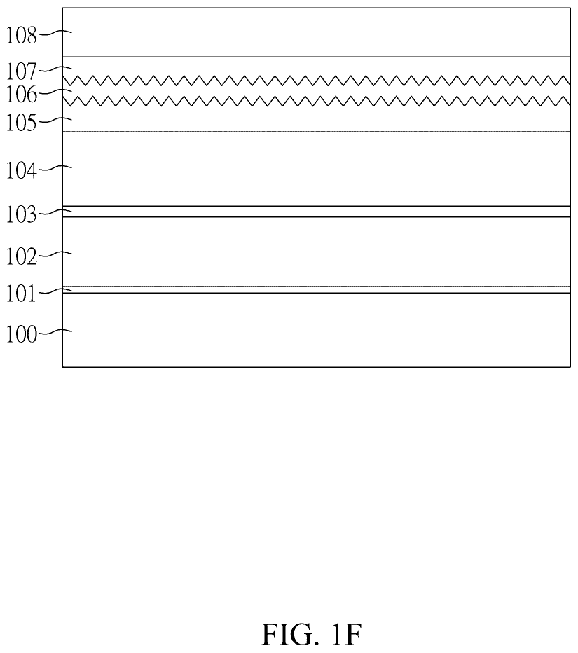

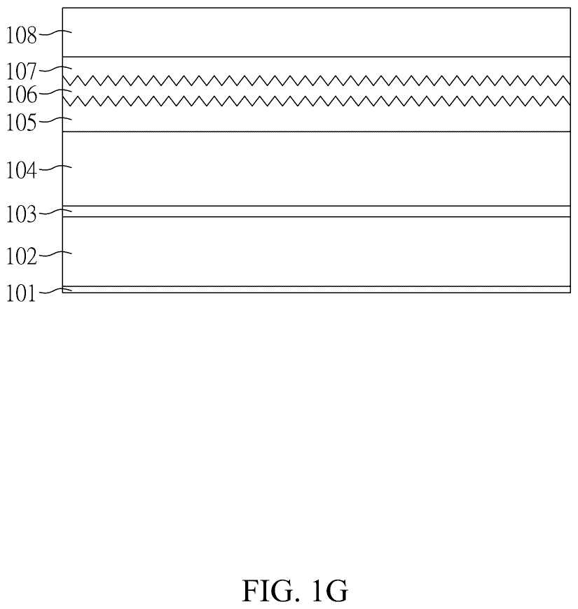

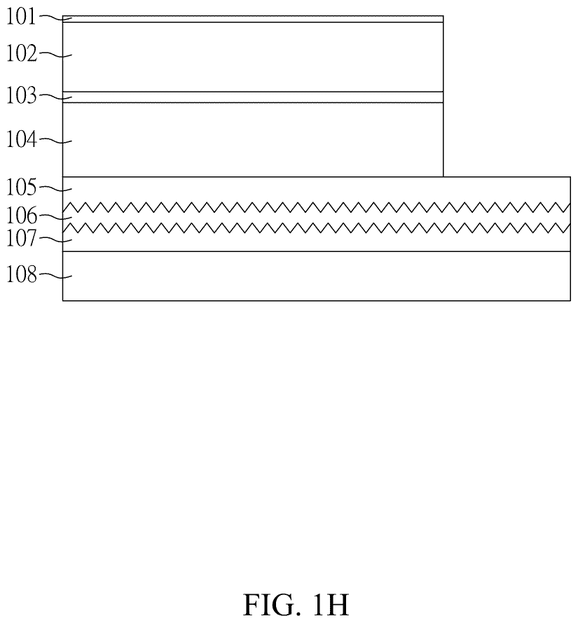

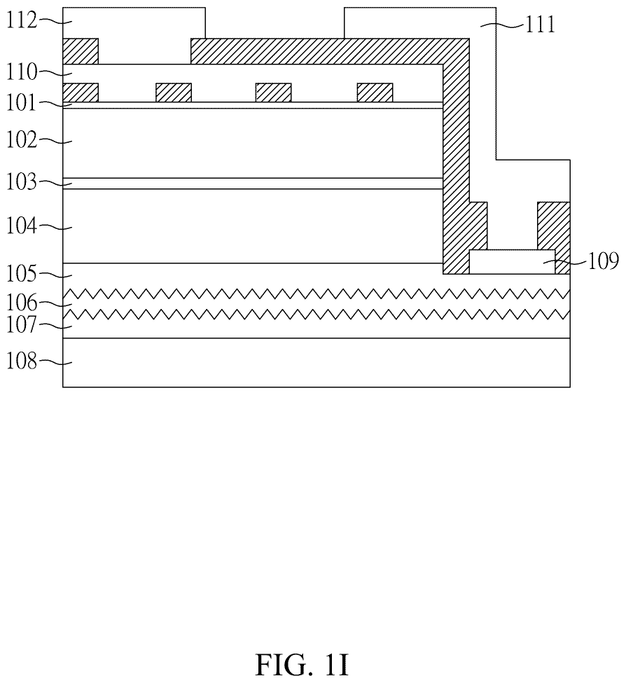

This invention discloses a flip-chip light-emitting diode and a manufacturing method thereof. Please refer to FIG. 1A, which shows an epitaxial growth of a buffer layer (not shown) and an N-type ohmic contact layer 101 on an epitaxial growth substrate 100 using Metal Organic Chemical Vapor Deposition (MOCVD) or Molecular Beam Epitaxy (MBE) technology. Specifically, the epitaxial growth substrate 100 is a gallium arsenide (GaAs) substrate, but is not limited thereto. Furthermore, the buffer layer may be an indium phosphide (InP) epitaxial layer, an indium gallium phosphide (InGaP) epitaxial layer, an aluminum indium phosphide (AlInP) epitaxial layer, or an aluminum gallium arsenide (AlGaAs) epitaxial layer, used to adjust lattice matching between the epitaxial growth substrate and the subsequent epitaxial composite layer during growth, reducing stress caused by lattice mismatch in the subsequent epitaxial process, thereby improving the film quality of the subsequent epitaxial layers.

Next, the N-type ohmic contact layer 101 is specifically an N-type indium gallium phosphide (InGaP) epitaxial layer, with a lattice constant between that of gallium arsenide (GaAs) and the multiple quantum well structure. Therefore, the N-type indium gallium phosphide epitaxial layer can also serve as a buffer layer, further facilitating lattice matching for subsequent epitaxial layers. Additionally, the N-type indium gallium phosphide epitaxial layer can optimize carrier injection efficiency, adjusting its bandgap based on the ratio of gallium and indium to control the transport of electrons and holes, ensuring more carriers are effectively injected into the light-emitting layer for enhancing light emission efficiency. In particular, the N-type ohmic contact layer 101 serves as an interface for ohmic contact with the N-type electrode. Thus, commonly used dopants in the N-type indium gallium arsenide epitaxial layer include sulfur(S), selenium (Se), or silicon (Si), with a doping concentration typically ranging from 10¹⁸ to 10²⁰ cm⁻³. This concentration range helps reduce the Schottky barrier, thereby achieving low-resistance ohmic contact.

Subsequently, an epitaxial composite layer is grown on the N-type ohmic contact layer 101, comprising a first compound semiconductor layer 104, a light-emitting layer 103, and a second compound semiconductor layer 102. The light-emitting layer 103 is formed by a multiple quantum well (MQW) structure made of ternary compound semiconductors such as indium gallium arsenide (InGaAs) or aluminum gallium arsenide (AlGaAs), or quaternary compound semiconductors such as aluminum indium gallium arsenide (AlInGaAs) or indium gallium arsenide phosphide (InGaAsP), and is sandwiched between the first compound semiconductor layer 104 and the second compound semiconductor layer 102, with the second compound semiconductor layer 102 disposed on the N-type ohmic contact layer 101. In this embodiment, the emission wavelength range of the multiple quantum well may be 660 to 1000 nanometers (nm), but is not limited thereto. Specifically, the first compound semiconductor layer 104 is a first conductive type (P-type) aluminum gallium arsenide (AlGaAs) epitaxial layer, and the second compound semiconductor layer 102 is a second conductive type (N-type) aluminum gallium arsenide (AlGaAs) epitaxial layer. It should be noted that the materials described in the above embodiment are merely exemplary, and the present invention is not limited thereto. In practical applications, the materials and their compositions may be adjusted based on the emission wavelength.

As shown in FIG. 1A, a compound semiconductor layer is further epitaxially grown on the epitaxial composite layer. In a specific embodiment, this compound semiconductor layer is a P-type ohmic contact layer 105, such as, but not limited to, a carbon-doped gallium phosphide (GaP) epitaxial layer, with a preferred thickness of 100 to 1000 angstroms (Å). In particular, the doping concentration of this carbon-doped gallium phosphide epitaxial layer is between 10¹⁸ and 10²⁰ cm⁻³, which helps reduce contact resistance to form an ohmic contact with the subsequent metal layer interface.

Please refer to FIG. 1B, the P-type ohmic contact layer 105 undergoes surface roughening treatment to enhance the light extraction efficiency of the light-emitting layer. Subsequently, a physical vapor deposition (PVD) process for a wafer bonding composite layer is performed. Specifically, a titanium dioxide (TiO2) layer 106 is vacuum-sputtered onto the roughened surface of the P-type ohmic contact layer 105, as shown in FIG. 1C. Preferably, the thickness of the titanium dioxide layer 106 is 200 to 300 angstroms (Å). Specifically, since titanium dioxide has a high refractive index of approximately 2.4 to 2.7 in the red and infrared light wavelength range, compared to other oxide layers, such as aluminum oxide (Al₂O₃) with a refractive index of only 1.6, the use of the high-refractive-index titanium dioxide layer 106 instead of a low-refractive-index aluminum oxide facilitates the passage of light generated by the light-emitting layer through the titanium dioxide layer 106, increasing light extraction efficiency and enhancing the brightness of the light-emitting diode.

Next, as shown in FIG. 1D, a silicon dioxide (SiO₂) layer 107 is deposited on the titanium dioxide layer 106, such that the titanium dioxide layer 106 and the silicon dioxide layer 107 collectively serve as a wafer bonding composite layer to facilitate subsequent wafer bonding. It should be noted that the wafer bonding composite layer with one titanium dioxide layer 106 and one silicon dioxide layer 107 is merely one embodiment of the present invention. In another embodiment, the wafer bonding composite layer comprises a plurality of titanium dioxide layers 106 and a plurality of silicon dioxide layers 107, with each titanium dioxide layer 106 and each silicon dioxide layer 107 alternately stacked.

Subsequently, a wafer bonding process is performed to bond the epitaxial growth substrate 100 to another transparent substrate 108. Before wafer bonding, as shown in FIG. 1E, a planarization process, such as chemical mechanical polishing (CMP), must be performed to planarize the upper surface of the silicon dioxide layer 107. Then, surface activation treatment is conducted, for example, using oxygen (O₂) or argon (Ar) plasma to further activate the surface of the silicon dioxide layer 107, generating more hydroxyl (—OH) groups to facilitate initial bonding. Please refer to FIG. 1F, the wafer bonding is performed by aligning the surfaces of the transparent substrate 108 and the silicon dioxide layer 107 side of the epitaxial growth substrate 100, applying pressure, and increasing the temperature to ensure successful bonding of the two wafers. After the transparent substrate 108 and the epitaxial growth substrate 100 are bonded, the epitaxial growth substrate 100 and the buffer layer are removed from the opposite side of the transparent substrate 108, exposing the N-type ohmic contact layer 101, as shown in FIG. 1G. The aforementioned transparent substrate 108 may be, but is not limited to, one of a sapphire (Al₂O₃) substrate, a gallium nitride (GaN) substrate, a zinc oxide (ZnO) substrate, a gallium arsenide (GaAs) substrate, and an indium phosphide (InP) substrate.

Please refer to FIG. 1H, a mesa etching process is performed to etch portions of the N-type ohmic contact layer 101 and the epitaxial composite layer, i.e., portions of the N-type ohmic contact layer 101, the first compound semiconductor layer 104, the light-emitting layer 103, and the second compound semiconductor layer 102, for exposing a flat surface of the P-type ohmic contact layer 105 for forming an electrode thereon subsequently. Please refer to FIG. 1I, a metal evaporation process is then performed to form a first conductive type electrode 109 on the P-type ohmic contact layer 105. The first conductive type electrode 109 may be, for example, but not limited to, gold (Au), beryllium gold (BeAu) alloy, or the like. On the other hand, a second conductive type electrode 110 is formed on the N-type ohmic contact layer 101, electrically connected to the epitaxial composite layer. The second conductive type electrode 110 may be, for example, but not limited to, nickel (Ni), gold (Au), germanium gold (GeAu) alloy, or the like. In particular, the first conductive type electrode 109 and the second conductive type electrode 110 are disposed on the same side of the transparent substrate 108 to facilitate the layout arrangement of electrode pads for subsequent flip-chip processing. Subsequently, a metallization process for the two electrode pads is performed. As shown in FIG. 1I, a first conductive type electrode pad 111 is formed in electrical connection with the first conductive type electrode 109, and a second conductive type electrode pad 112 is formed in electrical connection with the second conductive type electrode 110. Moreover, the first conductive type electrode pad 111 and the second conductive type electrode pad 112 are disposed on the same level on the same side of the transparent substrate 108, completing the final structure of the flip-chip light-emitting diode in one embodiment of this invention. The materials of the first conductive type electrode pad 111 and the second conductive type electrode pad 112 are selected from the group consisting of titanium (Ti), platinum (Pt), gold (Au), and combinations thereof.

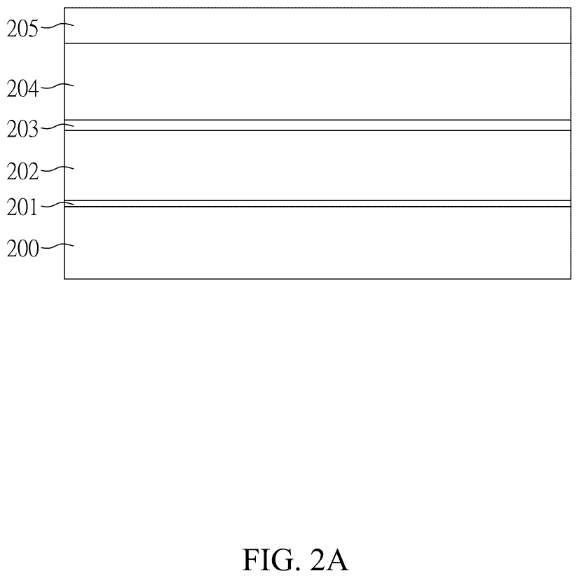

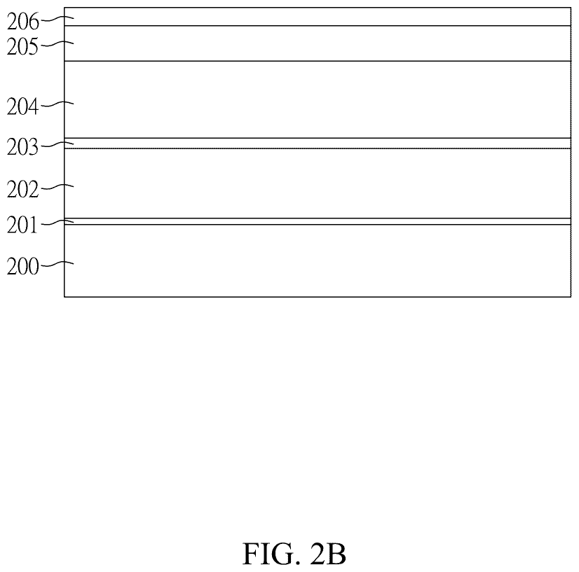

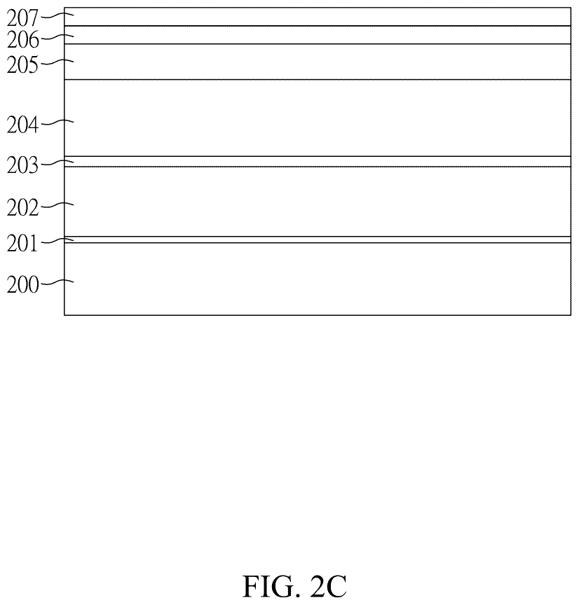

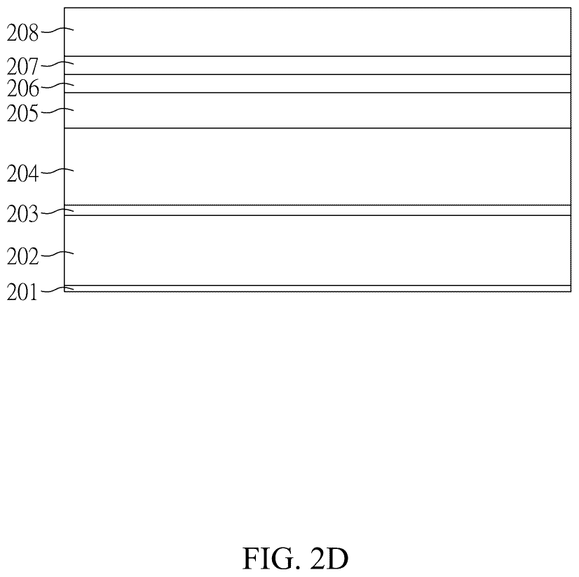

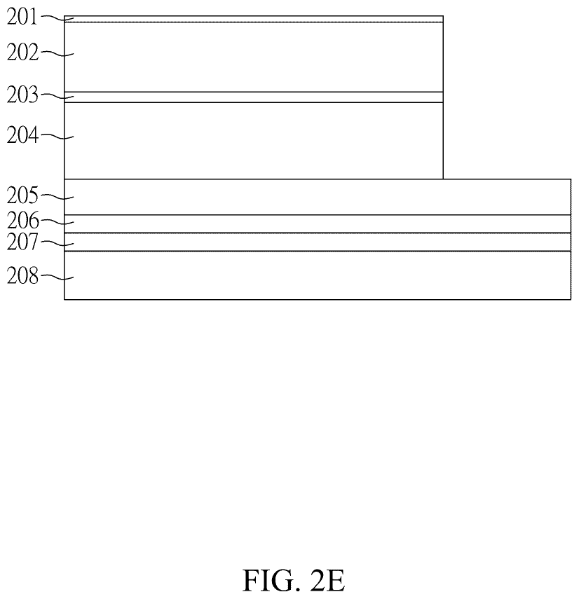

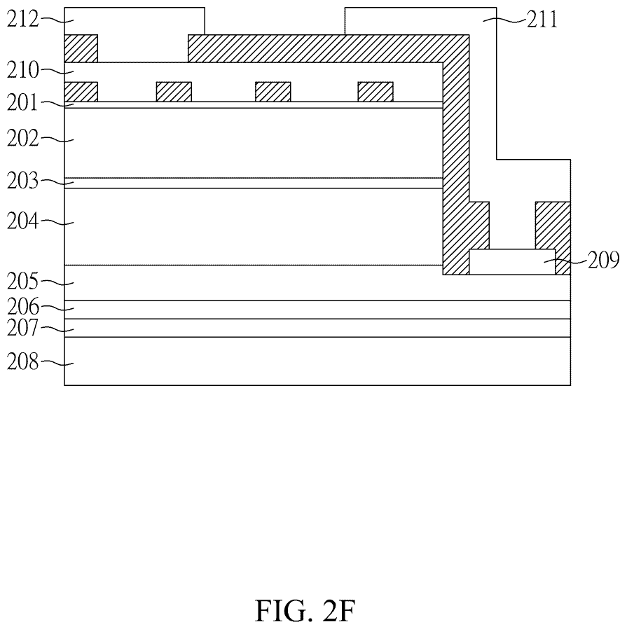

Please refer to FIG. 2A to FIG. 2F, which show schematic diagrams illustrating the manufacturing of a flip-chip light-emitting diode in another embodiment of this invention. Elements identical to those in the previous embodiment can be referred to the aforementioned content, and differences from the previous embodiment will be specifically described below. As shown in FIG. 2A, an epitaxial growth substrate 200 has a buffer layer (not shown), an N-type ohmic contact layer 201, an epitaxial composite layer, and a P-type ohmic contact layer 205. The epitaxial composite layer comprises a first compound semiconductor layer 204, a light-emitting layer 203, and a second compound semiconductor layer 202. The materials and processes of the aforementioned substrate and related compound semiconductor layers can be referred to the content described in the previous embodiment and will not be repeated here.

Please refer to FIG. 2B to FIG. 2C together, a deposition process for a wafer bonding composite layer is performed. Specifically, a titanium dioxide layer 206 is vacuum-sputtered onto the surface of the P-type ohmic contact layer 205, with a thickness of 200 to 300 angstroms (Å). Subsequently, a silicon dioxide layer 207 is deposited on the titanium dioxide layer 206, such that the titanium dioxide layer 206 and the silicon dioxide layer 207 collectively serve as a wafer bonding composite layer to facilitate subsequent wafer bonding. It should be noted that, unlike the previous embodiment, since the titanium dioxide in the wafer bonding composite layer of this embodiment has a high refractive index for light in the red and infrared wavelength ranges emitted by the light-emitting layer, enabling excellent light extraction efficiency for the light-emitting diode, the P-type ohmic contact layer 205 in this embodiment does not require surface roughening and can maintain a flat surface. Consequently, the titanium dioxide layer 206 and the silicon dioxide layer 207 of the wafer bonding composite layer deposited on the surface of the P-type ohmic contact layer 205 can maintain a relatively flat surface. Thus, prior to wafer bonding, there is no need for a planarization process, such as CMP in this embodiment for allowing direct wafer bonding of the transparent substrate 208 to the wafer bonding composite layer of the epitaxial growth substrate 200. Therefore, compared to the previous embodiment, this embodiment can omit complex CMP processes and related costs, enabling the flip-chip light-emitting diode of this embodiment to achieve both high brightness and low cost, enhancing the market competitiveness of the product.

Next, please refer to FIG. 2D to FIG. 2F, which show the process of wafer bonding the transparent substrate 208 to the silicon dioxide layer 207 of the wafer bonding composite layer, followed by the removal of the epitaxial growth substrate 200. Subsequently, a mesa etching process and the formation of two electrodes (i.e., the first conductive type electrode 209 and the second conductive type electrode 210) and two electrode pads (the first conductive type electrode pad 211 and the second conductive type electrode pad 212) are performed to complete the final structure of the flip-chip light-emitting diode in this embodiment. The materials and processes for the related components can be referred to the content of the previous embodiment and will not be repeated here.

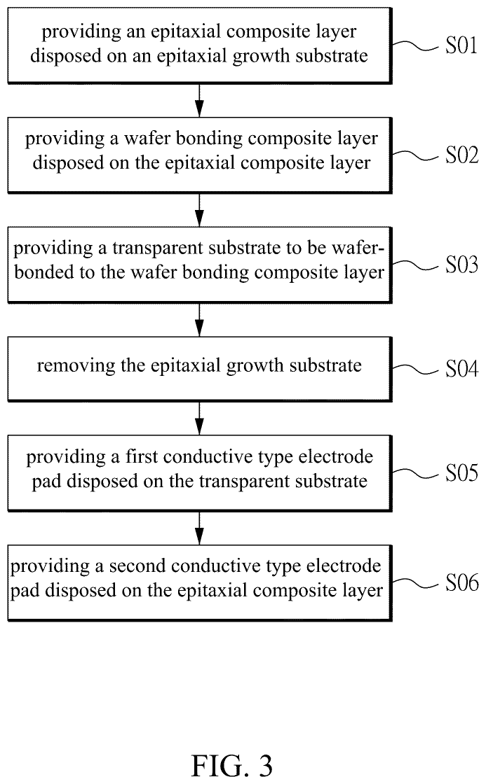

Please refer to FIG. 3, which shows a flowchart schematic of the manufacturing process of the flip-chip light-emitting diode of this invention. First, in step S01, an epitaxial composite layer is provided, disposed on an epitaxial growth substrate. In step S02, a wafer bonding composite layer is provided, disposed on the epitaxial composite layer, wherein the wafer bonding composite layer comprises at least one titanium dioxide (TiO₂) layer and at least one silicon dioxide (SiO2) layer. Next, in step S03, a transparent substrate is provided to be wafer-bonded to the wafer bonding composite layer. In step S04, the epitaxial growth substrate is removed. In step S05, a first conductive type electrode pad is provided, disposed on the transparent substrate, electrically connected to the epitaxial composite layer. Finally, in step S06, a second conductive type electrode pad is provided, disposed on the epitaxial composite layer, electrically connected to the epitaxial composite layer, and configured on the same level as the first conductive type electrode pad on the same side of the transparent substrate. The descriptions of the related components in the aforementioned process steps can be referred to the above content and will not be repeated here.

The above embodiments are used only to illustrate the implementations of the present invention and to explain the technical features of the present invention, and are not used to limit the scope of the present invention. Any modifications or equivalent arrangements that can be easily accomplished by people skilled in the art are considered to fall within the scope of the present invention, and the scope of the present invention should be limited by the claims of the patent application.

What is claimed is:

1. A flip-chip light-emitting diode, comprising:
a transparent substrate;
an epitaxial composite layer disposed on the transparent substrate;
a first conductive type electrode pad disposed on the transparent substrate, electrically connected to the epitaxial composite layer;
a second conductive type electrode pad disposed on the epitaxial composite layer, electrically connected to the epitaxial composite layer, and configured on the same level as the first conductive type electrode pad on the same side of the transparent substrate; and
a wafer bonding composite layer comprising at least one titanium dioxide (TiO₂) layer and at least one silicon dioxide (SiO₂) layer, sandwiched between the epitaxial composite layer and the transparent substrate.

2. The flip-chip light-emitting diode of claim 1, wherein the thickness of the at least one titanium dioxide layer is 200 to 300 angstroms (Å).

3. The flip-chip light-emitting diode of claim 1, wherein the wafer bonding composite layer comprises a plurality of titanium dioxide layers and a plurality of silicon dioxide layers, with each titanium dioxide layer and each silicon dioxide layer alternately stacked.

4. The flip-chip light-emitting diode of claim 1, wherein the epitaxial composite layer comprises a first compound semiconductor layer, a light-emitting layer, and a second compound semiconductor layer, wherein the first compound semiconductor layer and the second compound semiconductor layer sandwich the light-emitting layer, and the first compound semiconductor layer is disposed between the light-emitting layer and the transparent substrate.

5. The flip-chip light-emitting diode of claim 4, wherein the first compound semiconductor layer is a first conductive type aluminum gallium arsenide (AlGaAs) layer, and the second compound semiconductor layer is a second conductive type aluminum gallium arsenide layer.

6. The flip-chip light-emitting diode of claim 5, further comprising an ohmic contact layer sandwiched between the first conductive type aluminum gallium arsenide layer and the at least one titanium dioxide layer.

7. The flip-chip light-emitting diode of claim 6, wherein the ohmic contact layer is a gallium phosphide (GaP) layer.

8. The flip-chip light-emitting diode of claim 6, wherein the interface between the ohmic contact layer and the at least one titanium dioxide layer is a roughened surface.

9. The flip-chip light-emitting diode of claim 6, wherein the interface between the ohmic contact layer and the at least one titanium dioxide layer is a flat surface.

10. The flip-chip light-emitting diode of claim 1, wherein the transparent substrate is one of a sapphire (Al₂O₃) substrate, a gallium nitride (GaN) substrate, a zinc oxide (ZnO) substrate, a gallium arsenide (GaAs) substrate, and an indium phosphide (InP) substrate.

11. A manufacturing method of a flip-chip light-emitting diode, comprising:
providing an epitaxial composite layer disposed on an epitaxial growth substrate;
providing a wafer bonding composite layer disposed on the epitaxial composite layer, wherein the wafer bonding composite layer comprises at least one titanium dioxide (TiO2) layer and at least one silicon dioxide (SiO2) layer;
providing a transparent substrate to be wafer-bonded to the wafer bonding composite layer;
removing the epitaxial growth substrate;
providing a first conductive type electrode pad disposed on the transparent substrate and electrically connected to the epitaxial composite layer; and
providing a second conductive type electrode pad disposed on the epitaxial composite layer, electrically connected to the epitaxial composite layer, and configured on the same level as the first conductive type electrode pad on the same side of the transparent substrate.

12. The manufacturing method of a flip-chip light-emitting diode of claim 11, wherein the at least one titanium dioxide layer has a thickness of 200 to 300 angstroms (Å).

13. The manufacturing method of a flip-chip light-emitting diode of claim 11, wherein the step of providing a wafer bonding composite layer is a step of forming a plurality of titanium dioxide layers and a plurality of silicon dioxide layers alternately on the epitaxial composite layer, such that each of the titanium dioxide layers and each of the silicon dioxide layers are alternately stacked.

14. The manufacturing method of a flip-chip light-emitting diode of claim 11, wherein the step of providing an epitaxial composite layer is a step of forming a first compound semiconductor layer, a light-emitting layer, and a second compound semiconductor layer, the first compound semiconductor layer and the second compound semiconductor layer sandwiching the light-emitting layer, and the second compound semiconductor layer being disposed between the light-emitting layer and the epitaxial growth substrate.

15. The manufacturing method of a flip-chip light-emitting diode of claim 14, wherein the first compound semiconductor layer is a first conductive type aluminum gallium arsenide (AlGaAs) layer, and the second compound semiconductor layer is a second conductive type aluminum gallium arsenide layer.

16. The manufacturing method of a flip-chip light-emitting diode of claim 15, further comprising a step of providing an ohmic contact layer sandwiched between the first conductive type aluminum gallium arsenide layer and the at least one titanium dioxide layer.

17. The manufacturing method of a flip-chip light-emitting diode of claim 16, wherein the ohmic contact layer is a gallium phosphide (GaP) layer.

18. The manufacturing method of a flip-chip light-emitting diode of claim 16, wherein the step of providing a wafer bonding composite layer is a step of forming a roughened surface on the ohmic contact layer and then forming the at least one titanium dioxide layer to cover the roughened surface.

19. The manufacturing method of a flip-chip light-emitting diode of claim 16, wherein the step of providing a wafer bonding composite layer is a step of forming the at least one titanium dioxide layer on a flat surface of the ohmic contact layer.

20. The manufacturing method of a flip-chip light-emitting diode of claim 11, wherein the step of providing a transparent substrate is to provide one of a sapphire (Al₂O₃) substrate, a gallium nitride (GaN) substrate, a zinc oxide (ZnO) substrate, a gallium arsenide (GaAs) substrate, and an indium phosphide (InP) substrate.
